(19) United States
(12) Patent Application Publication
(10) Pub. No.: US 2025/0081624 A1
(43) Pub. Date: Mar. 6, 2025

(54) SEMICONDUCTOR DEVICE

(71) Applicant: Sumitomo Electric Device Innovations, Inc., Yokohama-shi (JP)

(72) Inventor: Ryota NAKAMURA, Yokohama-shi (JP)

(73) Assignee: Sumitomo Electric Device Innovations, Inc., Yokohama-shi (JP)

(21) Appl. No.: 18/769,561

(22) Filed: Jul. 11, 2024

(30) Foreign Application Priority Data
Sep. 6, 2023 (JP) 2023-144724

(51) Int. Cl. H01L 27/02

(52) U.S. Cl. CPC H10D 89/10

(57) ABSTRACT

A semiconductor device includes a substrate, first FETs having first gate electrodes and arranged in a first direction, second FETs having second gate electrodes and arranged in the first direction, third FETs having third gate electrodes and arranged in the first direction, the second FETs being interposed between the third and the first FETs in a second direction, wherein a first distance between two second gate electrodes with one second gate electrode interposed therebetween in a central portion of the first to third FETs in the first direction is larger than a second distance between two second gate electrodes with one second gate electrode interposed therebetween in a first end portion of the first to third FETs in the first direction, and the second distance is smaller than a third distance between two first gate electrodes with one first gate electrode interposed therebetween in the first end portion.

### REFERENCE TO RELATED APPLICATIONS

This application claims priority based on Japanese Patent Application No. 2023-144724 filed on Sep. 6, 2023, and the entire contents of the Japanese patent applications are incorporated herein by reference.

### FIELD OF THE INVENTION

A certain aspect of the embodiments is related to a semiconductor device.

### BACKGROUND OF THE INVENTION

In a field effect transistor (FET) having a finger-shaped source electrode, a finger-shaped gate electrode, and a finger-shaped drain electrode, a plurality of unit FETs having the source electrode, the gate electrode, and the drain electrode are arranged in an extending direction of the electrodes (for example, Patent Document 1: Japanese Laid-Open Patent Application No. 2002-299351, Patent Document 2: US Patent Publication No. 2017/0271329, and Patent Document 3: Japanese Laid-Open Patent Application No. 2022-135899).

### SUMMARY OF THE INVENTION

A semiconductor device according to the present disclosure includes: a substrate; a plurality of first FETs that have a plurality of first gate electrodes, respectively, and are arranged in a first direction on the substrate; a plurality of second FETs that have a plurality of second gate electrodes, respectively, and are arranged in the first direction; a plurality of third FETs that have a plurality of third gate electrodes, respectively, and are arranged in the first direction, the plurality of second FETs being interposed between the plurality of third FETs and the plurality of first FETs in a second direction intersecting the first direction; wherein a first distance between two second gate electrodes with one of the plurality of second gate electrodes interposed therebetween in a central portion of the plurality of first FETs, the plurality of second FETs and the plurality of third FETs in the first direction is larger than a second distance between two second gate electrodes with one of the plurality of second gate electrodes interposed therebetween in a first end portion close to a first edge of the plurality of first FETs, the plurality of second FETs and the plurality of third FETs in the first direction, and the second distance is smaller than a third distance between two first gate electrodes with one of the plurality of first gate electrodes interposed therebetween in the first end portion.

### BRIEF DESCRIPTION OF DRAWINGS

FIG. 1 is a plan view of a semiconductor device according to a first embodiment.

FIG. 2 is a cross-sectional view taken along a line A-A in FIG. 1.

FIG. 3 is a cross-sectional view taken along a line B-B in FIG. 1.

FIG. 4 is a diagram illustrating the arrangement of gate electrodes in a semiconductor device according to a first comparative example.

FIG. 5 is a diagram illustrating the arrangement of gate electrodes in a semiconductor device according to a second comparative example.

FIG. 6 is a diagram illustrating the arrangement of gate electrodes in the semiconductor device according to the first embodiment.

FIG. 7 is a diagram illustrating the arrangement of gate electrodes in a semiconductor device according to a second embodiment.

FIG. 8 is a diagram illustrating the arrangement of gate electrodes in a semiconductor device according to a third comparative example.

FIG. 9 is a plan view of a semiconductor device according to a third embodiment.

FIG. 10 is a plan view of a semiconductor device according to a first modification of the third embodiment.

FIG. 11 is a diagram illustrating a distance D with respect to a position X in a semiconductor device according to a fourth embodiment.

FIG. 12 is a diagram illustrating a distance D with respect to a position X in a semiconductor device according to a first modification of the fourth embodiment.

FIG. 13 is a diagram illustrating a distance D with respect to a position X in a semiconductor device according to a second modification of the fourth embodiment.

FIG. 14 is a diagram illustrating a distance D with respect to a position X in a semiconductor device according to a third modification of the fourth embodiment.

FIG. 15 is a diagram illustrating an arrangement of gate electrodes in a semiconductor device according to a fourth modification of the fourth embodiment.

FIG. 16 is a diagram illustrating an arrangement of gate electrodes in a semiconductor device according to a fifth modification of the fourth embodiment.

### DETAILED DESCRIPTION

In a semiconductor device in which a plurality of unit FETs are arranged, the unit FET located in the center has a lower heat dissipation property than the unit FETs located at the ends. Therefore, a temperature difference between the unit FET located in the center and the unit FETs located at the ends increases, and the characteristics of the unit FETs become uneven. This deteriorates the characteristics of the semiconductor device.

The present disclosure has been made in view of the above problems, and an object thereof is to suppress deterioration of the characteristics.

### Details of Embodiments of the Present Disclosure

First, the contents of the embodiments of this disclosure are listed and explained.
(1) A semiconductor device according to the present disclosure includes: a substrate; a plurality of first FETs that have a plurality of first gate electrodes, respectively, and are arranged in a first direction on the substrate; a plurality of second FETs that have a plurality of second gate electrodes, respectively, and are arranged in the first direction; a plurality of third FETs that have a plurality of third gate electrodes, respectively, and are arranged in the first direction, the plurality of second FETs being interposed between the plurality of third FETs and the plurality of first FETs in a second direction intersecting the first direction; wherein a first distance between two second gate electrodes with one of the plurality of second gate electrodes interposed therebetween in a central portion of the plurality of first FETs, the plurality of second FETs and the plurality of third FETs in the first direction is larger than a second distance between two second gate electrodes with one of the plurality of second gate electrodes interposed therebetween in a first end portion close to a first edge of the plurality of first FETs, the plurality of second FETs and the plurality of third FETs in the first direction, and the second distance is smaller than a third distance between two first gate electrodes with one of the plurality of first gate electrodes interposed therebetween in the first end portion. This allows heat to be dissipated from the second FETs in the first end portion. Therefore, since the temperature distribution of the semiconductor device can be made uniform, the characteristics of the FETs can be made uniform. Therefore, the deterioration of the characteristics of the semiconductor device can be suppressed.
(2) In the above (1), the first distance may be larger than a fourth distance between two first gate electrodes with one of the plurality of first gate electrodes interposed therebetween in the central portion. This makes it possible to make the temperature distribution of the FETs more uniform. Therefore, the deterioration of the characteristics of the semiconductor device can be further suppressed.
(3) In the above (1), the second distance may be smaller than a fifth distance between two third gate electrodes with one of the plurality of third gate electrodes interposed therebetween in the first end portion. This makes it possible to make the temperature distribution of the FETs more uniform. Therefore, the deterioration of the characteristics of the semiconductor device can be further suppressed.
(4) In the above (3), the first distance may be larger than a fourth distance between two first gate electrodes with one of the plurality of first gate electrodes interposed therebetween in the central portion. The first distance may be larger than a sixth distance between two third gate electrodes with one of the plurality of third gate electrodes interposed therebetween in the central portion. This makes it possible to make the temperature distribution of the FETs more uniform. Therefore, the deterioration of the characteristics of the semiconductor device can be further suppressed.
(5) In any one of the above (1) to (4), a seventh distance between two second gate electrodes with one of the plurality of second gate electrodes interposed therebetween in an intermediate portion between the central portion and the first end portion in the first direction may be larger than the second distance and smaller than the first distance. This makes it possible to make the temperature distribution of the FETs more uniform. Therefore, the deterioration of the characteristics of the semiconductor device can be further suppressed.
(6) In the above (1), the first distance is larger than an eighth distance between two second gate electrodes with one of the plurality of second gate electrodes interposed therebetween in a second end portion closer to a second edge opposite to the first edge of the plurality of first FETs, the plurality of second FETs and the plurality of third FETs than the center portion. This makes it possible to make the temperature distribution of the FETs more uniform. Therefore, the deterioration of the characteristics of the semiconductor device can be further suppressed.
(7) In the above (4), the first distance may be larger than an eighth distance between two second gate electrodes with one of the plurality of second gate electrodes interposed therebetween in a second end portion closer to a second edge opposite to the first edge of the plurality of first FETs, the plurality of second FETs and the plurality of third FETs than the center portion. The eighth distance may be smaller than a ninth distance between two first gate electrodes with one of the plurality of first gate electrodes interposed therebetween in the second end portion. The eighth distance may be smaller than a tenth distance between two third gate electrodes with one of the plurality of third gate electrodes interposed therebetween in the second end portion. This makes it possible to make the temperature distribution of the FETs more uniform. Therefore, the deterioration of the characteristics of the semiconductor device can be further suppressed.
(8) In any one of the above (1) to (7), the third distance and the fourth distance may be the same as each other. This facilitates the design of the FETs.
(9) In any one of the above (1) to (8), the number of the first FETs, the number of the second FETs, and the number of the third FETs may be the same as each other. This allows the first to the third source electrodes to be electrically connected to each other, and the first to the third drain electrodes to be electrically connected to each other.
(10) In any one of the above (1) to (9), the plurality of first FETs may include a plurality of first source electrodes and a plurality of first drain electrodes, and each of the plurality of first gate electrodes may be interposed between one of the plurality of first source electrodes and one of the first drain electrodes in the first direction. The plurality of second FETs may include a plurality of second source electrodes and a plurality of second drain electrodes, and each of the plurality of second gate electrodes may be interposed between one of the plurality of second source electrodes and one of the plurality of second drain electrodes in the first direction. The third FETs may include a plurality of third source electrodes and a plurality of third drain electrodes, and each of the third gate electrodes may be interposed between one of the third source electrodes and one of the third drain electrodes in the first direction. This allows the plurality of FETs to be configured.
(11) In the above (10), the substrate may include a first active region, a second active region, a third active region, a first inactive region provided between the first active region and the second active region, and a second inactive region provided between the second active region and the third active region. The plurality of first FETs may be provided in the first active region. The plurality of second FETs may be provided in the second active region. The plurality of third FETs may be provided in the third active region. Each of the plurality of first source electrodes may be connected to a corresponding second source electrode in the first inactive region. Each of the plurality of first drain electrodes may be connected to a corresponding second drain electrode in the first inactive region. Each of the plurality of second source electrodes may be connected to a corresponding third source electrode in the second inactive region. Each of the plurality of second drain electrodes may be connected to a corresponding third drain electrode in the second inactive region. This allows the first to the third source electrodes to be electrically connected to each other, and the first to the third drain electrodes to be electrically connected to each other.

Specific examples of a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

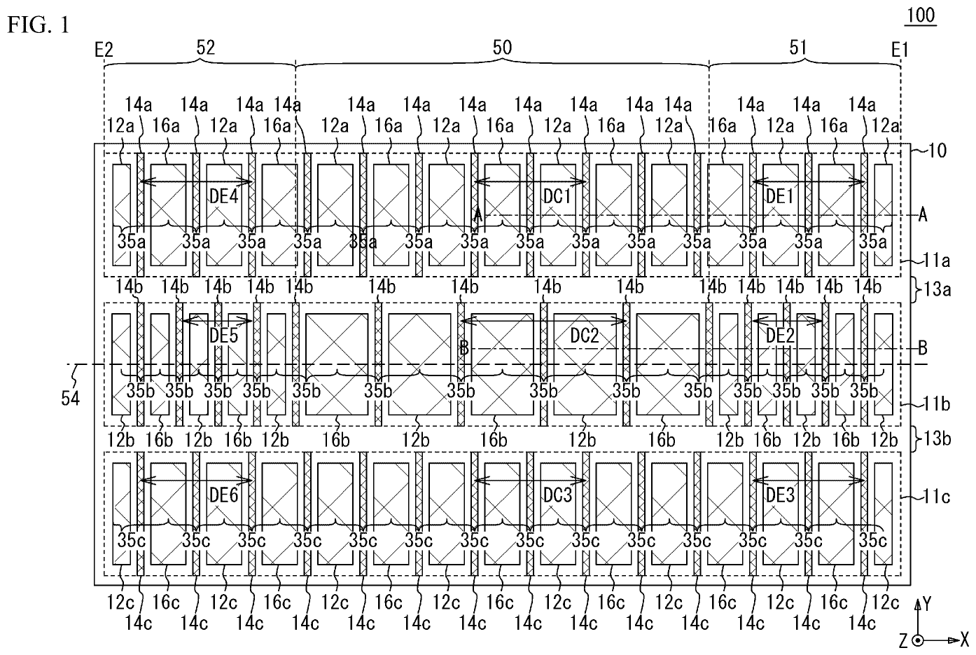

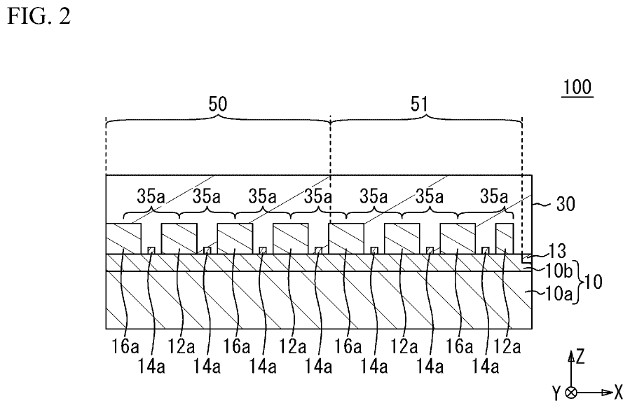

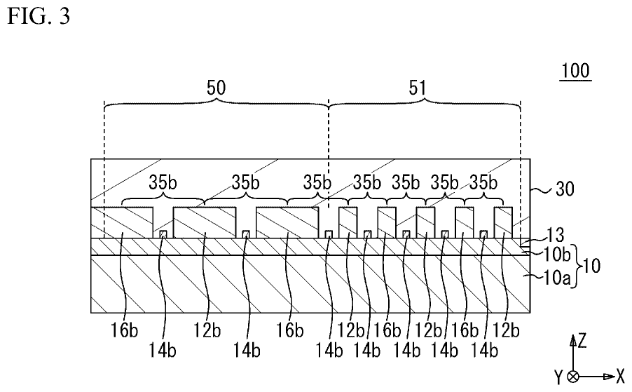

A semiconductor device used in an amplifier for amplifying a high frequency signal of, for example, 0.5 GHz to 10 GHz in a base station of mobile communication will be described as an example. FIG. 1 is a plan view of a semiconductor device according to a first embodiment. FIGS. 2 and 3 are cross-sectional views taken along a line A-A and a line B-B in FIG. 1, respectively. A thickness direction of a substrate 10 is defined as a Z direction, an extending direction of finger-shaped source electrodes 12a to 12c, finger-shaped gate electrodes 14a to 14c and finger-shaped drain electrodes 16a to 16c is defined as a Y direction (a second direction intersecting with a first direction), and an arrangement direction of the source electrodes 12a to 12c, the gate electrodes 14a to 14c and the drain electrodes 16a to 16c is defined as an X direction (a first direction).

As illustrated in FIGS. 1 to 3, in a semiconductor device 100 of the first embodiment, the substrate 10 includes a substrate 10a and a semiconductor layer 10b provided on the substrate 10a. In an XY plane parallel to the X direction and the Y direction, regions in which the semiconductor layer 10b is inactivated by ion implantation or the like are inactive regions 13, 13a, and 13b, and regions in which the semiconductor layer 10b is not inactivated (that is, regions in which a part of the substrate 10 is activated) are active regions 11a to 11c. The active regions 11a to 11c extend in the X direction. The active regions 11a to 11c are arranged in the Y direction. The inactive region 13a (first inactive region) is defined between the active regions 11a and 11b in the Y direction. The inactive region 13b (second inactive region) is defined between the active regions 11b and 11c in the Y direction.

A plurality of unit FETs 35a (first FETs) are arranged in the X direction on the active region 11a (first active region) of the substrate 10. A plurality of unit FETs 35b (second FETs) are arranged in the X direction on the active region 11b (second active region) of the substrate 10. A plurality of unit FETs 35c (third FETs) are arranged in the X direction on the active region 11c (third active region) of the substrate 10.

The unit FET 35a includes the source electrode 12a (first source electrode), the gate electrode 14a (first gate electrode), and the drain electrode 16a (first drain electrode). The source electrode 12a and the drain electrode 16a are alternately provided in the X direction. One of the gate electrodes 14a is provided between one of the source electrodes 12a and one of the drain electrodes 16a.

The unit FET 35b includes the source electrode 12b (second source electrode), the gate electrode 14b (second gate electrode), and the drain electrode 16b (second drain electrode). The source electrode 12b and the drain electrode 16b are alternately provided in the X direction. One of the gate electrodes 14b is provided between one of the source electrodes 12b and one of the drain electrodes 16b.

The unit FET 35c includes the source electrode 12c (third source electrode), the gate electrode 14c (third gate electrode), and the drain electrode 16c (third drain electrode). The source electrode 12c and the drain electrode 16c are alternately provided in the X direction. One of the gate electrodes 14c is provided between one of the source electrodes 12c and one of the drain electrodes 16c.

An insulating layer 30 is provided on the substrate 10 so as to cover the unit FETs 35a to 35c. In FIGS. 1 to 3, a source wiring electrically connecting the source electrodes 12a to 12c, a gate wiring electrically connecting the gate electrodes 14a to 14c, and a drain wiring electrically connecting the drain electrodes 16a to 16c are not illustrated.

The plurality of unit FETs 35a, the plurality of unit FETs 35b, and the plurality of unit FETs 35c overlap each other when viewed from the Y direction. Each of the unit FETs 35a to 35c has a central portion 50 in the X direction, an end portion 51 closer to an edge E1 than the central portion 50, and an end portion 52 closer to an edge E2 opposite to the edge E1 than the central portion 50.

Each of the gate electrodes 14a to 14c is linear and extends in the Y direction. Respective distances between the source electrodes 12a to 12c and the gate electrodes 14a to 14c are substantially equal to each other, and respective distances between the gate electrodes 14a to 14c and the drain electrodes 16a to 16c are substantially equal to each other. The widths (gate lengths) of the gate electrodes 14a and 14c in the X direction are substantially equal to each other.

A distance between the gate electrodes 14a interposing the drain electrode 16a and a distance between the gate electrodes 14a interposing the source electrode 12a may be different from each other. Therefore, a distance D between the gate electrodes 14a is defined as a distance between two gate electrodes 14a with one gate electrode 14a interposed therebetween. A distance D between the gate electrodes 14b is defined as a distance between two gate electrodes 14b with one gate electrode 14b therebetween, and a distance D between the gate electrodes 14c is defined as a distance between two gate electrodes 14c with one gate electrode 14c therebetween.

In the plurality of unit FETs 35a, the plurality of distances D in the X direction between two gate electrodes 14a with one gate electrode 14a interposed therebetween are substantially equal. In the plurality of unit FETs 35c, the plurality of distances D in the X direction between two gate electrodes 14c with one gate electrode 14c interposed therebetween are substantially equal. That is, in the plurality of gate electrodes 14a, a distance DC1 in the central portion 50, a distance DE1 in the end portion 51, and a distance DE4 in the end portion 52 are equal to each other. In the plurality of gate electrodes 14c, a distance DC3 in the central portion 50, a distance DE3 in the end portion 51, and a distance DE6 in the end portion 52 are equal to each other.

In the plurality of unit FETs 35b, a distance between two gate electrodes 14b with one gate electrode 14b interposed therebetween in the central portion 50 is larger than distances between two gate electrodes 14b with one gate electrode 14b interposed therebetween in the end portions 51 and 52. That is, in the plurality of gate electrodes 14b, a distance DC2 in the central portion 50 is larger than distances DE2 and DE5 in the end portions 51 and 52.

The positions of the edges E1 are substantially coincident with each other in the plurality of unit FETs 35a, 35b, and 35c. The positions of the edges E2 are substantially coincident with each other in the plurality of unit FETs 35a, 35b, and 35c. That is, the unit FET 35a closest to the edge E1, the unit FET 35b closest to the edge E1, and the unit FET 35c closest to the edge E1 overlap each other when viewed from the Y direction. The unit FET 35a closest to the edge E2, the unit FET 35b closest to the edge E2, and the unit FET 35c closest to the edge E2 overlap each other when viewed from the Y direction. The numbers of plurality of unit FETs 35a, 35b, and 35c are the same as each other.

In such an arrangement, when the distance DC2 is made larger than the distances DE2 and DE5, the distance DC2 is larger than the distances DC1 and DC3, the distance DE2 is smaller than the distances DE1 and DE3, and the distance DE5 is smaller than the distances DE4 and DE6.

When the semiconductor device 100 is, for example, a nitride semiconductor device, the substrate 10a is, for example, a silicon carbide (SiC) substrate, a silicon (Si) substrate, a gallium nitride (GaN) substrate, or a sapphire (Al₂O₃) substrate. The semiconductor layer 10b includes a nitride semiconductor layer such as a gallium nitride layer, an aluminum gallium nitride (AlGaN) layer, and/or an indium gallium nitride (InGaN) layer. When the unit FETs 35a to 35c are GaN HEMTs (Gallium Nitride High Electron Mobility Transistors), the semiconductor layer 10b includes a gallium nitride channel layer provided on the substrate 10a and an aluminum gallium nitride barrier layer provided on the channel layer. When the semiconductor device 100 is, for example, a gallium arsenide (GaAs)-based semiconductor device, the substrate 10a is, for example, a gallium arsenide substrate. The semiconductor layer 10b includes an arsenide semiconductor layer such as a gallium arsenide layer, an aluminum gallium arsenide (AlGaAs) layer and/or an indium gallium arsenide (InGaAs) layer. The semiconductor device 100 may be a silicon semiconductor device such as LDMOS (Laterally Diffused Metal Oxide Semiconductor).

The source electrodes 12a to 12c and the drain electrodes 16a to 16c are metal films, for example, include a titanium film and an aluminum film formed in this order on the substrate 10. The gate electrodes 14a to 14c are metal films, for example, include a nickel film and a gold film formed in this order on the substrate 10. A low-resistance metal layer may be provided on the source electrodes 12a to 12c and the drain electrodes 16a to 16c. The metal layer is, for example, a gold layer, and has a lower resistivity than the resistivities of the source electrodes 12a to 12c and the drain electrodes 16a to 16c. The insulating layer 30 is, for example, an inorganic insulating layer such as a silicon nitride layer or a silicon oxide layer, an organic insulating layer such as a polyimide layer or a BCB (Benzocyclobutene) layer, or a laminated film of an inorganic insulating layer and an organic insulating layer.

The width of each of the source electrodes 12a to 12c in the X direction is, for example, 5 μm to 150 μm. The gate length of each of the gate electrodes 14a to 14c in the X direction is, for example, 0.25 μm to 2 μm. The width of each of the drain electrodes 16a to 16c in the X direction is, for example, 5 μm to 150 μm. The gate widths of the unit FETs 35a to 35c in the Y direction are, for example, 100 μm to 400 μm.

### First Comparative Example

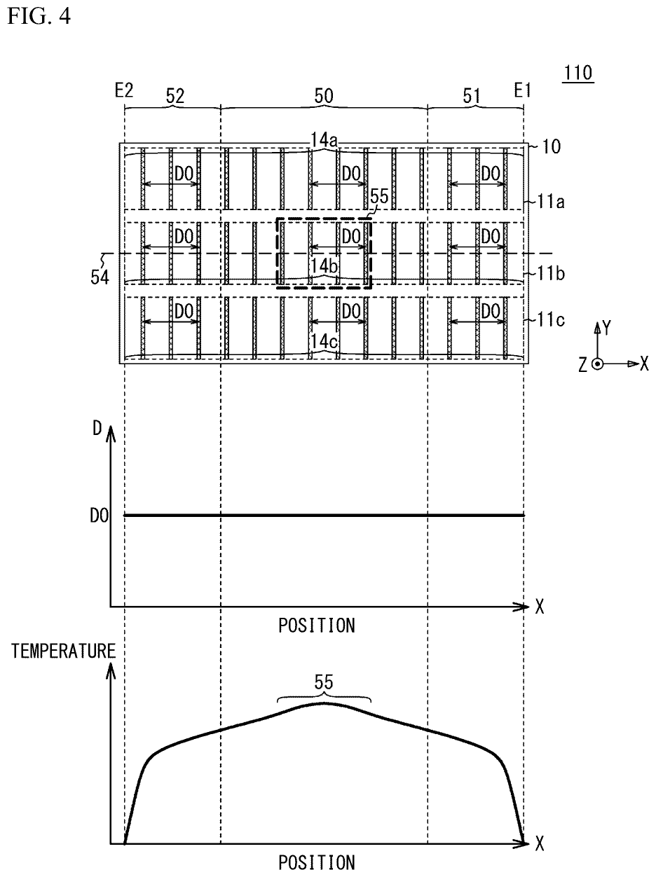

FIG. 4 is a diagram illustrating the arrangement of gate electrodes in a semiconductor device according to a first comparative example. An upper diagram of FIG. 4 is a plan view illustrating the arrangement of the gate electrodes 14a to 14c in a semiconductor device 110 of the first comparative example. A middle diagram of FIG. 4 is a diagram illustrating the distances D in the X direction between two gate electrodes 14a to 14c with one gate electrode 14a to 14c interposed therebetween with respect to a position in the X direction of the semiconductor device 110. A lower diagram of FIG. 4 is an image diagram illustrating a temperature at a center line 54 in the Y direction of the semiconductor device 110 with respect to a position in the X direction.

As illustrated in the upper and middle views of FIG. 4, the distances D in all of the gate electrodes 14a to 14c is equal to each other and are the distances D0. Heat generated in the plurality of unit FETs 35a and 35c and the unit FETs 35b located in the end portions 51 and 52 is likely to diffuse to the surroundings. On the other hand, the heat generated in the unit FET 35b in the central portion 50 is less likely to be diffused to the surroundings. As a result, as illustrated in the lower diagram of FIG. 4, the temperature of the unit FET 35b in a region 55 near the center in the X direction increases. Therefore, the temperature difference between the unit FET 35b in the region 55 and the unit FETs 35a to 35c in the end portions 51 and 52 increases. Therefore, the characteristics such as the high frequency characteristics of the unit FETs 35a to 35c become uneven. Accordingly, the characteristics of the semiconductor device 110 are deteriorated.

### Second Comparative Example

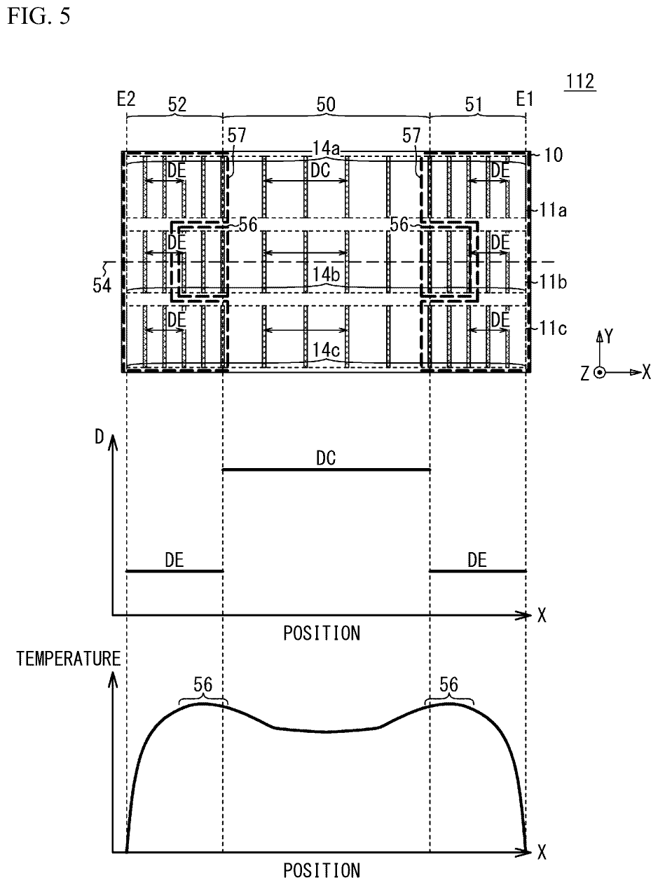

FIG. 5 is a diagram illustrating the arrangement of gate electrodes in a semiconductor device according to a second comparative example. An upper diagram of FIG. 5 is a plan view illustrating the arrangement of the gate electrodes 14a to 14c in a semiconductor device 112 of the second comparative example. A middle diagram of FIG. 5 is a diagram illustrating the distances D in the X direction between two gate electrodes 14a to 14c with one gate electrode 14a to 14c interposed therebetween with respect to a position in the X direction of the semiconductor device 112. A lower diagram of FIG. 5 is an image diagram illustrating a temperature at the center line 54 in the Y direction of the semiconductor device 112 with respect to a position in the X direction.

As illustrated in the upper and middle diagrams of FIG. 5, the distances DC in the central portion 50 are made larger than the distances DE in the end portions 51 and 52. The distances DC of the gate electrodes 14a to 14c in the central portion 50 are equal to each other, and the distances DE of the gate electrodes 14a to 14c in the end portions 51 and 52 are equal to each other.

In the central portion 50 of the unit FETs 35b, the density of the gate electrodes 14b in the X direction is low. Therefore, the heat generation in the central portion 50 of the unit FETs 35b is small, and the temperature in the central portion 50 of the unit FETs 35b can be lowered. The density of the gate electrodes 14b in the X direction in the end portions 51 and 52 is increased. The heat generation in the end portions 51 and 52 of the unit FETs 35a to 35c is increased. The unit FETs 35b in regions 56 near the central portion 50 in the end portions 51 and 52 are surrounded from three directions by regions 57 having a high density of the gate electrodes 14a to 14c. The remaining direction is a direction toward the central portion 50. Therefore, the heat generated in the unit FETs 35b in the regions 56 is less likely to diffuse. Therefore, as illustrated in the lower diagram of FIG. 5, the temperature of the unit FETs 35b in the regions 56 increases. This increases the temperature distribution of the unit FETs 35a to 35c, and the characteristics such as the high frequency characteristics become uneven. Therefore, the characteristics of the semiconductor device 112 are deteriorated. Even if the distances DC and DE are changed to optimize the temperature distribution, it is difficult to reduce the temperature distribution of the unit FETs 35a to 35c.

### Description of First Embodiment

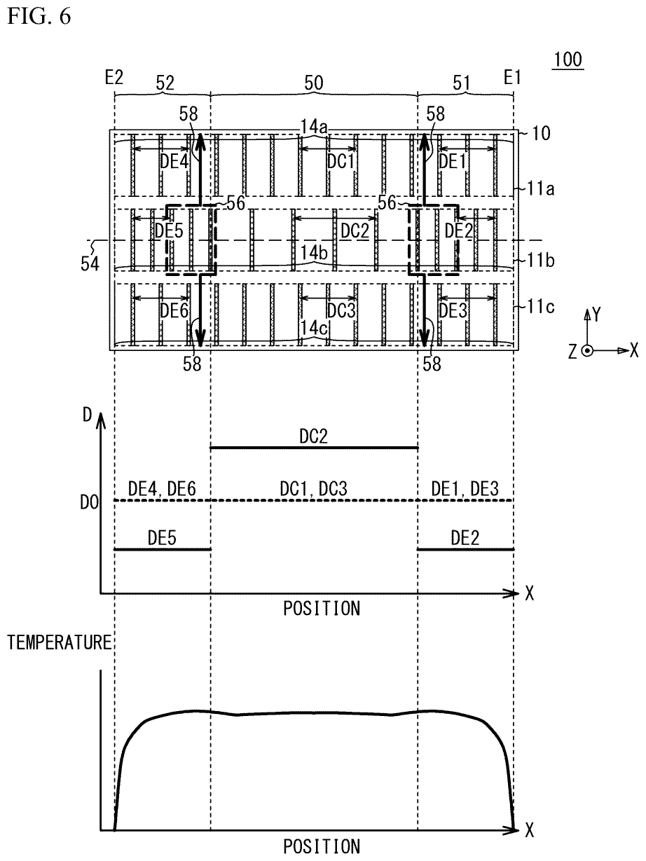

FIG. 6 is a diagram illustrating the arrangement of gate electrodes in the semiconductor device according to the first embodiment. The upper diagram of FIG. 6 is a plan view illustrating the arrangement of the gate electrodes 14a to 14c in the semiconductor device 100 of the first embodiment. The middle diagram of FIG. 6 is a diagram illustrating the distances D in the X direction between two gate electrodes 14a to 14c with one gate electrode 14a to 14c interposed therebetween with respect to a position in the X direction of the semiconductor device 100. The lower diagram of FIG. 6 is an image diagram illustrating a temperature at the center line 54 in the Y direction of the semiconductor device 100 with respect to a position in the X direction.

As illustrated in the upper and middle views of FIG. 6, the distance DC2 of the gate electrodes 14b in the central portion 50 is made larger than the distance DC1 of the gate electrodes 14a and the distance DC3 of the gate electrodes 14c. The distances DE2 and DE5 of the gate electrodes 14b in the end portions 51 and 52 are made smaller than the distances DE1 and DE4 of the gate electrodes 14a and the distances DE3 and DE6 of the gate electrodes 14c. The heat generation amount of each of the unit FETs 35a and 35c in the end portions 51 and 52 is smaller than the heat generation amount of the unit FET 35b in the end portions 51 and 52. Therefore, the heat generated in the end portions 51 and 52 of the unit FETs 35b is likely to diffuse in the +direction and the-direction in the Y direction as indicated by arrows 58. As a result, the temperature distribution of the unit FETs 35a to 35c becomes more uniform as illustrated in the lower diagram of FIG. 6. Therefore, the high frequency characteristics of the unit FETs 35a to 35c can be made more uniform, and the deterioration of the characteristics of the semiconductor device 100 can be suppressed.

### Second Embodiment

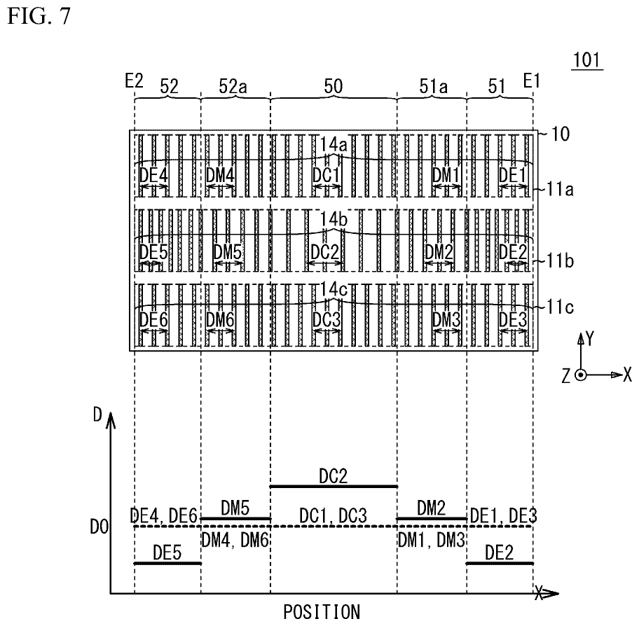

FIG. 7 is a diagram illustrating the arrangement of gate electrodes in a semiconductor device according to a second embodiment. An upper diagram of FIG. 7 is a plan view illustrating the arrangement of the gate electrodes 14a to 14c in a semiconductor device 101 of the second embodiment. A lower diagram is a diagram illustrating distances D in the X direction between two gate electrodes 14a to 14c with one gate electrode 14a to 14c interposed therebetween with respect to a position of the semiconductor device 101 in the X direction.

As illustrated in FIG. 7, in the semiconductor device 101 of the second embodiment, an intermediate portion 51a is provided between the end portion 51 and the central portion 50. An intermediate portion 52a is provided between the end portion 52 and the central portion 50. The distances D of the gate electrodes 14a to 14c in the intermediate portion 51a are distances DM1 to DM3, respectively. The distances D of the gate electrodes 14a to 14c in the intermediate portion 52a are distances DM4 to DM6, respectively. Each of the distances DM2 and DM5 is smaller than the distance DC2 and larger than each of the distances DE2 and DE5. Each of the distances DM1, DM3, DM4 and DM6 is equal to each of the distances DC1, DC3, DE1, DE3, DE4 and DE6. The other configurations of the second embodiment are the same as those of the first embodiment, and the description thereof is omitted.

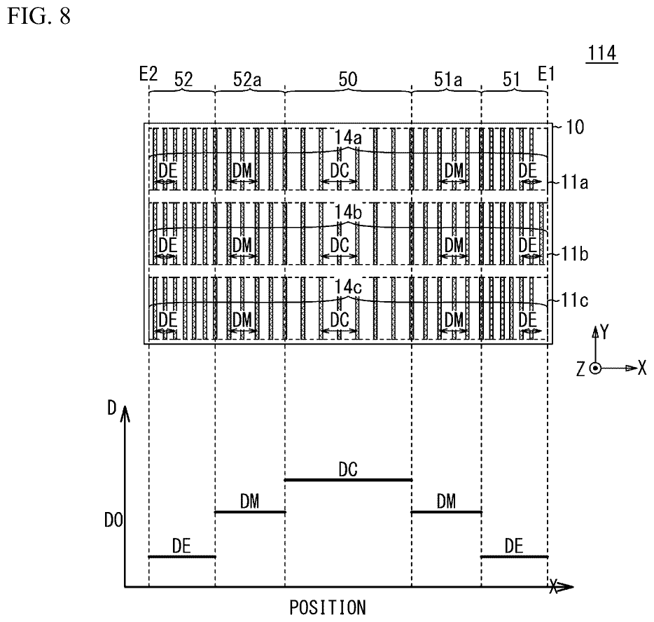

FIG. 8 is a diagram illustrating the arrangement of gate electrodes in a semiconductor device according to a third comparative example. An upper diagram of FIG. 8 is a plan view illustrating the arrangement of the gate electrodes 14a to 14c in a semiconductor device 114 of the third comparative example. The lower diagram is a diagram illustrating distances D in the X direction between two gate electrodes 14a to 14c with one gate electrode 14a to 14c interposed therebetween with respect to a position of the semiconductor device 114 in the X direction.

As illustrated in FIG. 8, in the semiconductor device 114 of the third comparative example, the distances D of the gate electrodes 14a to 14c in the central portion 50 are the distances DC and are equal to each other. The distances D of the gate electrodes 14a to 14c in the end portions 51 and 52 are the distances DE and are equal to each other. The distances D of the gate electrodes 14a to 14c in the intermediate portions 51a and 52a are distances DM and are equal to each other. The other configurations of the third comparative example are the same as those of the second embodiment.

### Simulation

The temperature distribution was simulated for the second embodiment and the third comparative example. In the simulation, parallel heat sources corresponding to the gate electrodes 14a to 14c were provided on the substrate 10, and the heat sources were heated by passing a current through the heat sources. The simulation conditions are as follows.
Substrate 10a: silicon carbide substrate having a thickness of 100 μm

Semiconductor layer 10b: gallium nitride layer having a thickness of 0.6 μm
Substrate 10: width in X direction is 3.26 mm, width in Y direction is 0.8 mm
Size of heat source: width in X direction is 5 μm, width in Y direction is 180 μm
Inactive regions 13a and 13b: width in Y direction is 10 μm
Central portion 50: the number of gate electrodes is 8
Each of Intermediate portions 51a and 52a: the number of gate electrodes is 5
Each of End portions 51 and 52: the number of gate electrodes is 6

### Distance D of Second Embodiment

DC2=210 μm, DM2, DM5=190 μm, DE2, DE5=170 μm
DC1, DC3, DM1, DM3, DM4, DM6, DE1, DE3, DE4, DE6=190 μm

### Distance D of Third Comparative Example

DC=210 μm, DM=190 μm, DE=170 μm

The values of the distances DC, DM and DE of the third comparative example are values optimized so that a maximum temperature is low. The values of the distances DC2, DM2, DM5, DE2, and DE5 of the second embodiment were the same as the optimized values of the distances DC, DM, and DE of the third comparative example. The distances DC1, DC3, DM1, DM3, DM4, DM6, DE1, DE3, DE4 and DE6 were equal to each other.

The maximum temperature on the substrate 10 is illustrated below in the simulation results in which the heat generation amounts of the respective heat sources are the same.
Second Embodiment: 108.2° C.
Third Comparative Example: 108.9° C.
   As described above, the maximum temperature of the second embodiment is lower than that of the third comparative example in which the distances DC, DM, and DE are optimized. The temperature distribution in the second embodiment is considered to be smaller than that in the third comparative example. Therefore, in the semiconductor device 101 of the second embodiment, the characteristics of the unit FETs 35a to 35c can be made uniform compared with the semiconductor device 114 of the third comparative example, and deterioration of the characteristics of the semiconductor device 101 can be suppressed.

### Third Embodiment

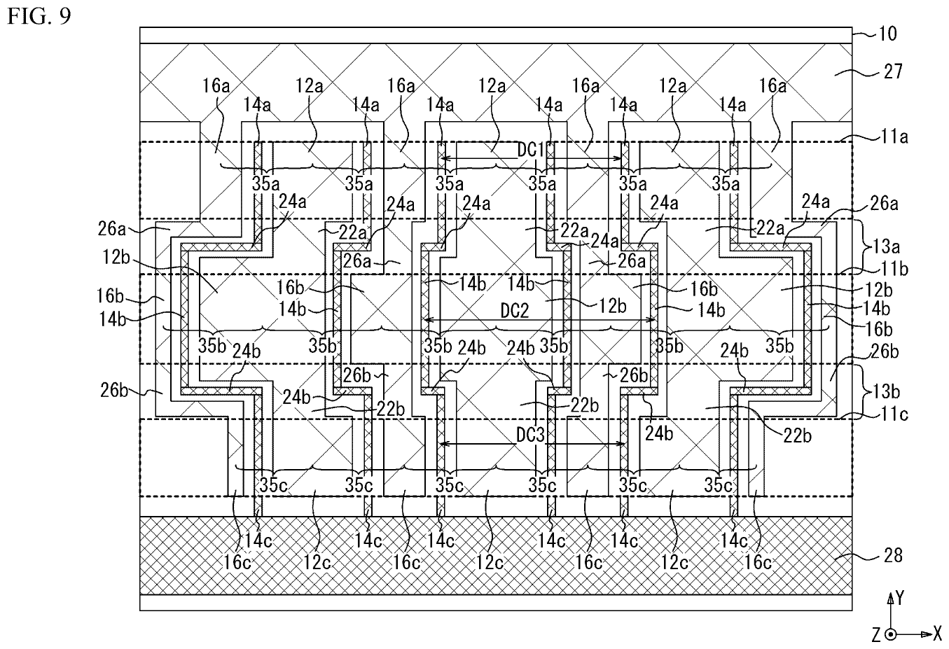

A third embodiment describes an example of source wirings, gate wirings, and drain wirings in the first and the second embodiments. FIG. 9 is a plan view of a semiconductor device according to the third embodiment. FIG. 9 illustrates a plan view of the central portion of the first and the second embodiments.

As illustrated in FIG. 9, the distance DC2 is larger than the distances DC1 and DC3. Source wirings 22a, gate wirings 24a, and drain wirings 26a are provided on the substrate 10 in the inactive region 13a between the active regions 11a and 11b. The source wiring 22a electrically connects the source electrodes 12a and 12b. The gate wiring 24a electrically connects the gate electrodes 14a and 14b. The drain wiring 26a electrically connects the drain electrodes 16a and 16b.

Source wirings 22b, gate wirings 24b, and drain wirings 26b are provided on the substrate 10 in the inactive region 13b between the active regions 11b and 11c. The source wiring 22b electrically connects the source electrodes 12b and 12c. The gate wiring 24b electrically connects the gate electrodes 14b and 14c. The drain wiring 26b electrically connects the drain electrodes 16b and 16c.

A drain bus bar 27 and a gate bus bar 28 are provided on the substrate 10 so as to interpose the unit FETs 35a to 35c therebetween. The drain bus bar 27 is electrically connected to the drain electrodes 16a to 16c. The gate bus bar 28 is electrically connected to the gate electrodes 14a to 14c.

The source electrodes 12a to 12c are electrically connected to a metal layer provided on the lower surface of the substrate 10 through via holes (not illustrated). The via holes penetrate the substrate 10 and are connected to the source electrodes 12a to 12c. The source electrodes 12a to 12c may be electrically connected to a source bus bar.

As a result, a source potential is supplied from the metal layer provided on the lower surface of the substrate 10 to the source electrodes 12a to 12c. A gate potential is supplied from the gate bus bar 28 to the gate electrodes 14a to 14c. A drain potential is supplied from the drain bus bar 27 to the drain electrodes 16a to 16c.

### First Modification of Third Embodiment

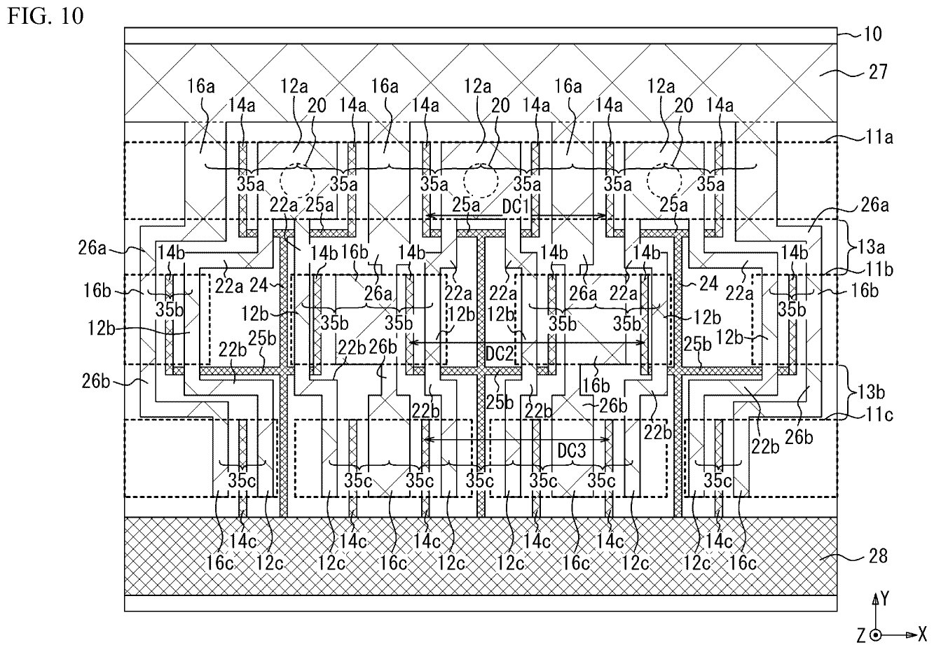

A first modification of the third embodiment describes an example of the source wirings, the gate wirings, and the drain wirings in the first and the second embodiments. FIG. 10 is a plan view of a semiconductor device according to a first modification of the third embodiment. FIG. 10 illustrates a plan view of the central portion of the first and the second embodiments.

As illustrated in FIG. 10, two source wirings 22a are connected to one source electrode 12a. The two source wirings 22a are connected to two source electrodes 12b, two source wirings 22b, and two source electrodes 12c, respectively. A gate wiring 24 is provided between the two source wirings 22a, the two source electrodes 12b, the two source wirings 22b, and the two source electrodes 12c. A end of the gate wiring 24 in the Y direction is electrically connected to the gate bus bar 28. In the inactive region 13a, the gate wiring 25a intersects the source wiring 22a without contacting it, and electrically connects the gate wiring 24 and the gate electrode 14a. In the inactive region 13b, the gate wiring 25b intersects the source wiring 22b without contacting it, and electrically connects the gate wiring 24 and the gate electrode 14b.

Thereby, the gate potential is directly supplied from the gate bus bar 28 to the gate electrodes 14c. The gate potential is supplied from the gate bus bar 28 to the gate electrodes 14a and 14b via the gate wirings 24, 25a and 25b. By providing the gate wiring 24, a gate resistance can be suppressed.

Each of via holes 20 penetrates the substrate 10, overlaps the source electrode 12a when viewed from the Z direction, and is electrically connected to the source electrode 12a. Thereby, the source potential is supplied from the metal layer provided on the lower surface of the substrate 10 to the source electrode 12a, the source potential is supplied from the source electrode 12a to the source electrode 12b via the source wiring 22a, and the source potential is supplied from the source electrode 12a to the source electrode 12c via the source wiring 22a, the source electrode 12b, and the source wiring 22b. The other configurations of the first modification of the third embodiment are the same as those of the third embodiment, and the description thereof is omitted.

### Fourth Embodiment

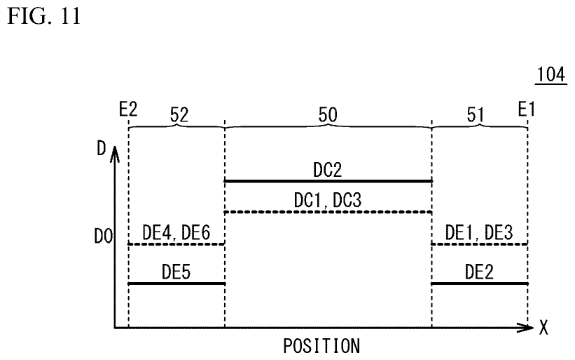

FIG. 11 is a diagram illustrating distances D with respect to a position X in the semiconductor device according to a fourth embodiment. As illustrated in FIG. 11, in a semiconductor device 104 of the fourth embodiment, the distances DC1 and DC3 of the gate electrodes 14a and 14c in the central portion 50 are larger than the distances DE1, DE3, DE4, and DE6 of the gate electrodes 14a and 14c in the end portions 51 and 52. The distance DC2 is larger than the distances DC1 and DC3, and the distances DE2 and DE5 are smaller than the distances DE1, DE3, DE4 and DE6. The other configurations of the fourth embodiment are the same as those of the first embodiment, and the description thereof is omitted. As illustrated in the fourth embodiment, the gate electrodes 14a and 14c may have different distances D in the central portion 50 and the end portions 51 and 52.

### First Modification of Fourth Embodiment

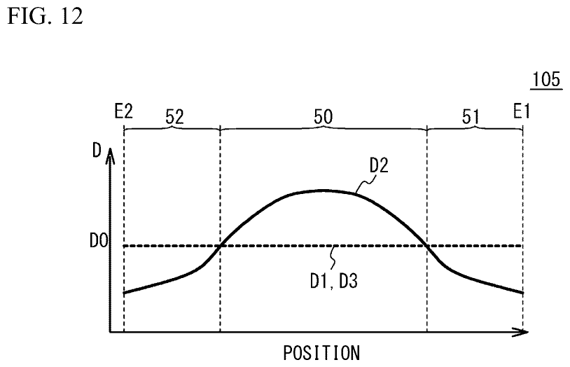

FIG. 12 is a diagram illustrating distances D with respect to a position X in a semiconductor device according to a first modification of the fourth embodiment. As illustrated in FIG. 12, in a semiconductor device 105 of the first modification of the fourth embodiment, a distance D2 of the gate electrodes 14b gradually increases from the edges E1 and E2 to the center. The distances D1 and D3 of the gate electrodes 14a and 14c are the distance D0 and are constant. The other configurations of the first modification of the fourth embodiment are the same as those of the first embodiment, and the description thereof is omitted. As illustrated in the first modification of the fourth embodiment, the distance D2 of the gate electrodes 14b may be changed gradually as the position X approaches the center in the X direction.

### Second Modification of Fourth Embodiment

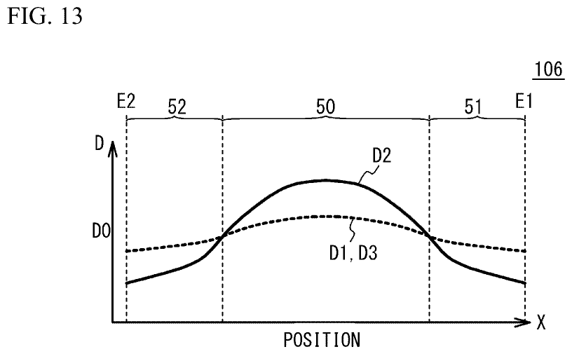

FIG. 13 is a diagram illustrating distances D with respect to a position X in the semiconductor device according to a second modification of the fourth embodiment. As illustrated in FIG. 13, in a semiconductor device 106 of the second modification of the fourth embodiment, the distances D1 and D3 of the gate electrodes 14a and 14c gradually increase from the edges E1 and E2 to the center. In the central portion 50, the distance D2 is larger than the distances D1 and D3, and in the end portions 51 and 52, the distance D2 is smaller than the distances D1 and D3. The other configurations of the second modification of the fourth embodiment are the same as those of the first modification of the fourth embodiment, and the description thereof is omitted. As illustrated in the second modification of the fourth embodiment, the distances D1 and D3 of the gate electrodes 14a and 14c may be changed gradually as the position X approaches the center in the X direction.

### Third Modification of Fourth Embodiment

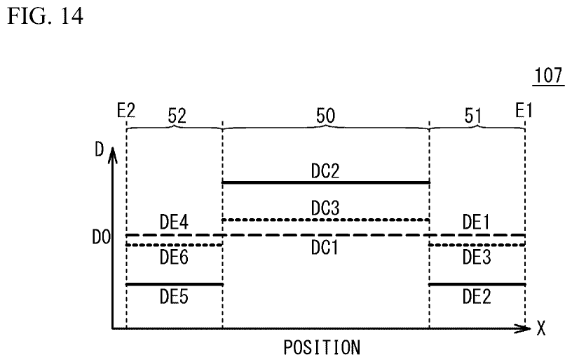

FIG. 14 is a diagram illustrating distances D with respect to a position X in the semiconductor device according to a third modification of the fourth embodiment. As illustrated in FIG. 14, in a semiconductor device 107 of the third modification of the fourth embodiment, the distances D of the gate electrodes 14a and 14b are the same as those of the first embodiment. The distances DC3, DE3 and DE6 of the gate electrode 14c are the same as those of the fourth embodiment. The other configurations of the third modification of the fourth embodiment are the same as those of the first embodiment, and the description thereof is omitted. As illustrated in the third modification of the fourth embodiment, the distances D of the gate electrodes 14a and 14c may be different from each other.

### Fourth Modification of the Fourth Embodiment

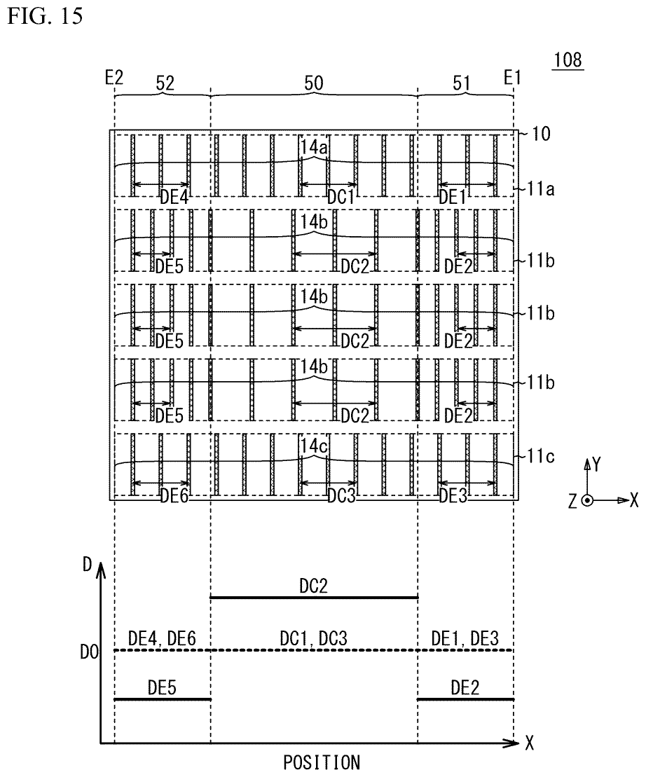

FIG. 15 is a diagram illustrating the arrangement of gate electrodes in a semiconductor device according to a fourth modification of the fourth embodiment. An upper diagram of the fourth modification of the fourth embodiment is a plan view illustrating the arrangement of the gate electrodes 14a to 14c in a semiconductor device 108 of the fourth modification of the fourth embodiment. The lower diagram is a diagram illustrating distances D in the X direction between two gate electrodes 14a to 14c with one gate electrode 14a to 14c interposed therebetween with respect to a position of the semiconductor device 108 in the X direction.

As illustrated in the upper diagram of FIG. 15, the gate electrodes 14b arranged in the X direction are provided in three rows in the Y direction between the gate electrodes 14a and 14c. The distances DC2 in the three rows of the unit FETs 35b are the same as each other. The distances DE2 in the three rows of the unit FETs 35b are the same as each other. The distances DE5 in the three rows of the unit FETs 35b are the same as each other. The other configurations of the fourth modification of the fourth embodiment are the same as those of the first embodiment, and the description thereof is omitted. As illustrated in the fourth modification of the fourth embodiment, the plurality of unit FETs 35b arranged in the X direction may be arranged in two or more rows in the Y direction.

### Fifth Modification of Fourth Embodiment

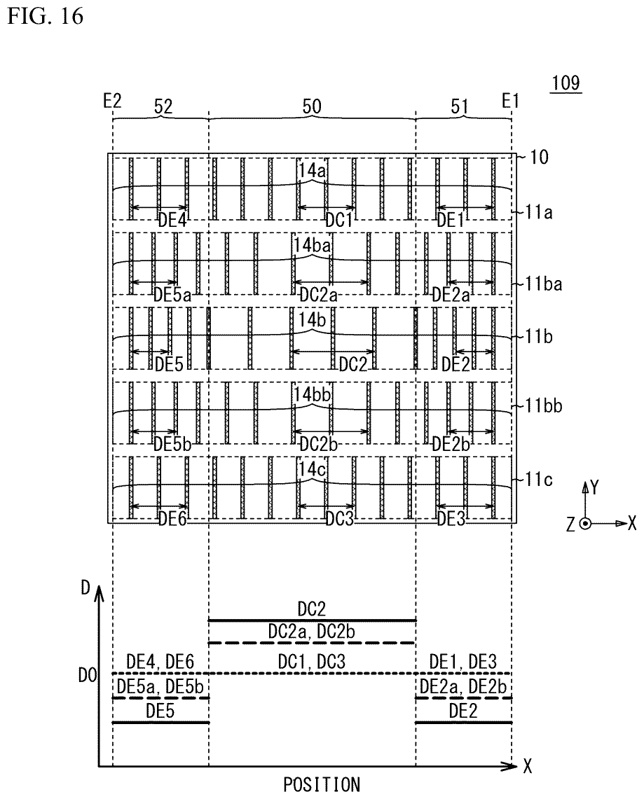

FIG. 16 is a diagram illustrating the arrangement of gate electrodes in a semiconductor device according to a fifth modification of the fourth embodiment. An upper diagram is a plan view illustrating the arrangement of the gate electrodes 14a to 14c in a semiconductor device 109 of the fifth modification of the fourth embodiment. A lower diagram is a diagram illustrating distances D in the X direction between two gate electrodes 14a to 14c with one gate electrode 14a to 14c interposed therebetween with respect to a position of the semiconductor device 109 in the X direction.

As illustrated in the upper diagram of FIG. 16, gate electrodes 14ba, 14b and 14bb are provided in three rows in the Y direction between the gate electrodes 14a and 14c. The distances D of the gate electrode 14ba in the central portion 50 and the end portions 51 and 52 are distances DC2a, DE2a, and DE5a, respectively. The distances D of the gate electrodes 14bb in the central portion 50 and the end portions 51 and 52 are distances DC2b, DE2b, and DE5b, respectively.

In the central portion 50, the distances DC2a and DC2b are smaller than the distance DC2 and larger than the distances DC1 and DC3. In the end portion 51, the distances DE2a and DE2b are larger than the distance DE2 and smaller than the distances DE1 and DE3. In the end portion 52, the distances DE5a and DE5b are larger than the distance DE5 and smaller than the distances DE4 and DE6. This makes it possible to make the temperature more uniform. The other configurations of the fifth modification of the fourth embodiment are the same as those of the fourth modification of the fourth embodiment, and the description thereof is omitted. When the plurality of unit FETs 35b are arranged in two or more rows in the Y direction as illustrated in the fifth modification of the fourth embodiment, the distances DC2a, DC2, and DC2b may be different from each other, the distances DE2a, DE2, and DE2b may be different from each other, and the distances DE5a, DE5, and DE5b may be different from each other.

According to the first to fourth embodiments and the modification thereof, the distance DC2 (first distance) between two gate electrodes 14b with one gate electrode 14b interposed therebetween in the central portion 50 of the unit FETs 35a to 35c in the X direction is larger than the distance DE2 (second distance) between two gate electrodes 14b with one gate electrode 14b interposed therebetween in the end portion 51 close to a first edge E1 of the unit FETs 35a to 35c in the X direction. The distance DE2 is smaller than the distance DE1 (third distance) between two gate electrodes 14a with one gate electrode 14a interposed therebetween in the end portion 51. Thereby, as illustrated in the upper diagram of FIG. 6, heat can be radiated from the region 56 in the end portion 51 as indicated by the arrow 58. Therefore, since the temperature distribution of the unit FETs 35a to 35c can be made uniform, the characteristics of the unit FETs 35a to 35c can be made uniform. Therefore, the deterioration of the characteristics of the semiconductor device can be suppressed.

The distance DC2 is larger than the distance DC1 (fourth distance) between two gate electrodes 14a with one gate electrode 14ba interposed therebetween in the central portion 50. This makes it possible to make the temperature distribution of the unit FETs 35a to 35c more uniform. Therefore, the deterioration of the characteristics of the semiconductor device can be further suppressed.

The distance DE2 is smaller than the distance DE3 (fifth distance) between two gate electrodes 14c with one gate electrode 14c interposed therebetween in the end portion 51. Thereby, as illustrated in the upper diagram of FIG. 6, heat can be radiated from the region 56 in the end portion 51 in-direction of the Y direction as indicated by the arrow 58. Therefore, the temperature distribution of the unit FETs 35a to 35c can be made more uniform. Therefore, the deterioration of the characteristics of the semiconductor device can be suppressed.

The distance DC2 is larger than the distance DC1 and is also larger than the distance DC3 (sixth distance) between the two gate electrodes 14c with one gate electrode 14c interposed therebetween in the central portion 50. This makes it possible to make the temperature distribution of the unit FETs 35a to 35c more uniform. Therefore, the deterioration of the characteristics of the semiconductor device can be further suppressed.

As illustrated in the second embodiment, the intermediate portion 51a is provided between the central portion 50 and the end portion 51 in the X direction. The distance DM2 (seventh distance) between the two gate electrodes 14b with one gate electrode 14b interposed therebetween in the intermediate portion 51a is larger than the distance DE2 and smaller than the distance DC2. This makes it possible to make the temperature distribution of the unit FETs 35a to 35c more uniform. Therefore, the deterioration of the characteristics of the semiconductor device can be further suppressed.

As illustrated in the first to the fourth embodiments and the modified examples thereof, the distance DC2 is larger than the distance DE5 (eighth distance) between two gate electrodes 14b with one gate electrode 14b interposed therebetween in the end portion 52 close to a second edge E2 opposite to the first edge E1. Thereby, as illustrated in the upper diagram of FIG. 6, heat can be radiated from the region 56 in the end portion 52 as indicated by the arrow 58. Therefore, the temperature distribution of the unit FETs 35a to 35c can be made more uniform. Therefore, the deterioration of the characteristics of the semiconductor device can be suppressed.

The distance DE5 is smaller than the distance DE4 (ninth distance) between the two gate electrodes 14a with one gate electrode 14a interposed therebetween in the end portion 52. The distance DE5 is smaller than the distance DE6 (tenth distance) between the two gate electrodes 14c with one gate electrode 14c interposed therebetween in the end portion 52. Thereby, as illustrated in the upper diagram of FIG. 6, heat can be radiated from the region 56 in the end portion 52 in both + and − directions of the Y direction as indicated by the arrow 58. Therefore, the temperature distribution of the unit FETs 35a to 35c can be made more uniform. Therefore, the deterioration of the characteristics of the semiconductor device can be suppressed.

The distances DC1 to DC3 are assumed to be the distances D of the gate electrodes 14a to 14c including the unit FETs 35a to 35c positioned at the centers of the plurality of unit FETs 35a to 35c in the X direction. The distances DE1 to DE6 are assumed to be the distances D of the gate electrodes 14a to 14c including the unit FETs 35a to 35c closest to the edge E1 or E2. At this time, the distance DC2 of the unit FET 35b can be se to 1.01 times or more, 1.05 times or more, or 1.1 times or more the distances DE2 and DE5. If a difference between the distance DC2 and the distances DE2 and DE5 is large, it is difficult to arrange the units FET 35b. From this viewpoint, the distance DC2 can be set to be 1.5 times or less the distances DE2 and DE5.

From the viewpoint of temperature uniformity, the distance DC2 can be set to 1.01 times or more, 1.05 times or more, or 1.1 times or more each of the distances DC1 and DC3. From the viewpoint of facilitating the arrangement, the distance DC2 can be set to be 1.5 times or less each of the distances DC1 and DC3. From the viewpoint of temperature uniformity, each of the distances DE2 and DE5 can be set to 0.99 times or less, 0.95 times or less, or 0.9 times or less each of the distances DE1, DE3, DE4, and DE6. From the viewpoint of facilitating the arrangement, each of the distances DE2 and DE5 can be set to 0.6 times or more each of the distances DE1, DE3, DE4 and DE6.

If the distances D are made different from each other in the plurality of unit FETs 35a and the distances D are made different from each other in the plurality of unit FETs 35c, it becomes difficult to design the unit FETs 35a and 35c. As illustrated in the first and the second embodiments and the fourth and the fifth modifications of the fourth embodiment, in the plurality of gate electrodes 14a, the distances DC1, DE1 and DE4 in the central portion 50 and the end portions 51 and 52 are the distance D0 and equal to each other. In the plurality of gate electrodes 14c, the distances DC3, DE3, and DE6 in the central portion 50 and the end portions 51 and 52 are the distance D0 and equal to each other. This facilitates the design of the unit FETs 35a and 35c. The distances D0 being equal to each other or substantially equal to each other allows a manufacturing error.

The number of the unit FETs 35a, the number of the unit FETs 35b, and the number of the unit FETs 35c are the same as each other. Thereby, as illustrated in the third embodiment and the first modification thereof, the source electrodes 12a to 12c of the corresponding unit FETs 35a to 35c can be electrically connected, and the drain electrodes 16a to 16c of the corresponding unit FETs 35a to 35c can be electrically connected.

The unit FET 35a includes the source electrode 12a and the drain electrode 16a with the gate electrode 14a interposed therebetween. The unit FET 35b includes the source electrode 12b and the drain electrode 16b with the gate electrode 14b interposed therebetween. The unit FET 35c includes the source electrode 12c and the drain electrode 16c with the gate electrode 14c interposed therebetween. This allows the unit FETs 35a to 35c to be configured.

As illustrated in the third embodiment and the first modification thereof, each of the plurality of source electrodes 12a is connected to the corresponding source electrode 12b in the inactive region 13a. Each of the plurality of drain electrodes 16a is connected to the corresponding drain electrode 16b in the inactive region 13a. Each of the plurality of source electrodes 12b is connected to a corresponding source electrode 12c in the inactive region 13b. Each of the plurality of drain electrodes 16b is connected to the corresponding drain electrode 16c in the inactive region 13b. This allows the unit FETs 35a and 35b and the unit FETs 35b and 35c to be electrically connected to each other.

Although the first to the fourth embodiments and the modification thereof have described the example in which 14 or 30 unit FETs 35a, 14 or 30 unit FETs 35b, and 14 or 30 unit FETs 35c are arranged in the X direction, it is sufficient that each of the plurality of unit FETs 35a, the plurality of unit FETs 35b and the plurality of unit FETs 35c is arranged in the X direction. Although the example in which the unit FETs 35a to 35c arranged in the X direction are arranged in three or five rows in the Y direction has been described, it is sufficient that the unit FETs 35a to 35c are arranged in three or more rows in the Y direction.

The embodiments disclosed here should be considered illustrative in all respects and not restrictive. The present disclosure is not limited to the specific embodiments described above, but various variations and changes are possible within the scope of the gist of the present disclosure as described in the claims.

1. A semiconductor device comprising:
a substrate;
a plurality of first FETs that have a plurality of first gate electrodes, respectively, and are arranged in a first direction on the substrate;
a plurality of second FETs that have a plurality of second gate electrodes, respectively, and are arranged in the first direction;
a plurality of third FETs that have a plurality of third gate electrodes, respectively, and are arranged in the first direction, the plurality of second FETs being interposed between the plurality of third FETs and the plurality of first FETs in a second direction intersecting the first direction;
wherein a first distance between two second gate electrodes with one of the plurality of second gate electrodes interposed therebetween in a central portion of the plurality of first FETs, the plurality of second FETs and the plurality of third FETs in the first direction is larger than a second distance between two second gate electrodes with one of the plurality of second gate electrodes interposed therebetween in a first end portion close to a first edge of the plurality of first FETs, the plurality of second FETs and the plurality of third FETs in the first direction, and
the second distance is smaller than a third distance between two first gate electrodes with one of the plurality of first gate electrodes interposed therebetween in the first end portion.

2. The semiconductor device according to claim 1, wherein
the first distance is larger than a fourth distance between two first gate electrodes with one of the plurality of first gate electrodes interposed therebetween in the central portion.

3. The semiconductor device according to claim 1, wherein
the second distance is smaller than a fifth distance between two third gate electrodes with one of the plurality of third gate electrodes interposed therebetween in the first end portion.

4. The semiconductor device according to claim 3, wherein
the first distance is larger than a fourth distance between two first gate electrodes with one of the plurality of first gate electrodes interposed therebetween in the central portion; and
the first distance is larger than a sixth distance between two third gate electrodes with one of the plurality of third gate electrodes interposed therebetween in the central portion.

5. The semiconductor device according to claim 1, wherein
a seventh distance between two second gate electrodes with one of the plurality of second gate electrodes interposed therebetween in an intermediate portion between the central portion and the first end portion in the first direction is larger than the second distance and smaller than the first distance.

6. The semiconductor device according to claim 1, wherein
the first distance is larger than an eighth distance between two second gate electrodes with one of the plurality of second gate electrodes interposed therebetween in a second end portion closer to a second edge opposite to the first edge of the plurality of first FETs, the plurality of second FETs and the plurality of third FETs than the center portion.

7. The semiconductor device according to claim 4, wherein
the first distance is larger than an eighth distance between two second gate electrodes with one of the plurality of second gate electrodes interposed therebetween in a second end portion closer to a second edge opposite to the first edge of the plurality of first FETs, the plurality of second FETs and the plurality of third FETs than the center portion,
the eighth distance is smaller than a ninth distance between two first gate electrodes with one of the plurality of first gate electrodes interposed therebetween in the second end portion; and
the eighth distance is smaller than a tenth distance between two third gate electrodes with one of the plurality of third gate electrodes interposed therebetween in the second end portion.

8. The semiconductor device according to claim 2, wherein
the third distance and the fourth distance are the same as each other.

9. The semiconductor device according to claim 1, wherein
the number of the first FETs, the number of the second FETs, and the number of the third FETs are the same as each other.

10. The semiconductor device according to claim 1, wherein
the plurality of first FETs include a plurality of first source electrodes and a plurality of first drain electrodes, and each of the plurality of first gate electrodes is interposed between one of the plurality of first source electrodes and one of the first drain electrodes in the first direction,
the plurality of second FETs include a plurality of second source electrodes and a plurality of second drain electrodes, and each of the plurality of second gate electrodes is interposed between one of the plurality of second source electrodes and one of the plurality of second drain electrodes in the first direction, and
the third FETs include a plurality of third source electrodes and a plurality of third drain electrodes, and each of the third gate electrodes is interposed between one of the third source electrodes and one of the third drain electrodes in the first direction.

11. The semiconductor device according to claim 10, wherein
the substrate includes a first active region, a second active region, a third active region, a first inactive region provided between the first active region and the second active region, and a second inactive region provided between the second active region and the third active region,
the plurality of first FETs are provided in the first active region,
the plurality of second FETs are provided in the second active region,
the plurality of third FETs are provided in the third active region,
each of the plurality of first source electrodes is connected to a corresponding second source electrode in the first inactive region,
each of the plurality of first drain electrodes is connected to a corresponding second drain electrode in the first inactive region,
each of the plurality of second source electrodes is connected to a corresponding third source electrode in the second inactive region, and
each of the plurality of second drain electrodes is connected to a corresponding third drain electrode in the second inactive region.
